(19) United States
(12) Patent Application Publication
(10) Pub. No.: US 2025/0100083 A1
(43) Pub. Date: Mar. 27, 2025

(54) METHOD FOR MANUFACTURING DISPLAY DEVICE AND LASER ABLATION DEVICE

(71) Applicant: Samsung Display Co., LTD., Yongin-si (KR)

(72) Inventor: SUKBONG LEE, Yongin-si (KR)

(21) Appl. No.: 18/889,609

(22) Filed: Sep. 19, 2024

(30) Foreign Application Priority Data
Sep. 25, 2023 (KR) 10-2023-0128577

(51) Int. Cl. B23K 26/402; B23K 26/08; B23K 26/082; B23K 101/36; B23K 103/00

(52) U.S. Cl. CPC B23K 26/402; B23K 26/082; B23K 26/083; B23K 2101/36; B23K 2103/42; B23K 2103/54

(57) ABSTRACT

A method for manufacturing a display device includes: forming a flexible substrate on a first side of a carrier substrate, forming a display element layer on the flexible substrate, sequentially irradiating a first laser beam and a second laser beam at a first time interval toward a second side of the carrier substrate opposite to the first side in a first area of the carrier substrate overlapping or adjacent to an edge part of the flexible substrate in a plan view, and sequentially irradiating the first laser beam and the second laser beam at a second time interval different from the first time interval in a second area of the carrier substrate where the display element layer is formed.

This application claims priority to Korean Patent Application No. 10-2023-0128577, and all the benefits accruing therefrom under 35 U.S.C. § 119, the content of which in its entirety is herein incorporated by reference.

### BACKGROUND

### 1. Technical Field

Embodiments provide generally to a method for manufacturing a display device and a laser ablation device. More particularly, embodiments relate to a method for manufacturing a flexible display device and a laser ablation device

### 2. Description of the Related Art

As information technology develops, the importance of display devices, which are communication media between users and information, is being highlighted. Accordingly, the use of display devices such as a liquid crystal display device, an organic light emitting display device, a plasma display device, and the like is increasing.

The display device may be implemented to be flexible using a plastic substrate with excellent flexibility. However, since the flexible substrate has great flexibility, the flexible substrate is desirable to be supported during the manufacturing process of the display device. Therefore, after forming the flexible substrate on a carrier substrate made of a material such as glass and the like, the display device manufacturing process is performed, and then the carrier substrate is removed.

The carrier substrate may be removed by various methods. For example, as a method of removing the carrier substrate, research is being actively conducted on a laser lift-off method using a laser.

### SUMMARY

Embodiments provide a method for manufacturing a display device using an excimer laser.

Embodiments provide a laser ablation device used in the method for manufacturing the display device.

A method for manufacturing a display device according to embodiments of the present disclosure includes: forming a flexible substrate on a first side of a carrier substrate, forming a display element layer on the flexible substrate, sequentially irradiating a first laser beam and a second laser beam at a first time interval toward a second side of the carrier substrate opposite to the first side in a first area of the carrier substrate overlapping or adjacent to an edge part of the flexible substrate in a plan view, and sequentially irradiating the first laser beam and the second laser beam at a second time interval different from the first time interval in a second area of the carrier substrate where the display element layer is formed.

In an embodiment, the first time interval may be smaller than the second time interval.

In an embodiment, an energy intensity of the first laser beam may be substantially the same as an energy intensity of the second laser beam.

In an embodiment, each of the first laser beam and the second laser beam may be an excimer laser.

In an embodiment, the method may further include disposing the flexible substrate on which the display element layer is formed and the carrier substrate on a stage after the forming the display element layer. The stage may be moveable in one direction together with the carrier substrate, the flexible substrate, and the display element layer while irradiating the first laser beam and the second laser beam.

In an embodiment, a movement velocity of the stage while the first and second laser beams irradiate the first area may be different from a movement velocity of the stage while the first and second laser beams irradiate the second area.

In an embodiment, a movement velocity of the stage while the first and second laser beams irradiate the first area may be smaller than a movement velocity of the stage while the first and second laser beams irradiate the second area.

In an embodiment, the flexible substrate may include a first polyimide layer and a second polyimide layer formed on the first polyimide layer.

In an embodiment, in sequentially irradiating the first laser beam and the second laser beam at the first time interval and sequentially irradiating the first laser beam and the second laser beam at the second time interval, the first laser beam and the second laser beam may irradiate the carrier substrate using a scan method.

In an embodiment, in sequentially irradiating the first laser beam and the second laser beam at the first time interval and sequentially irradiating the first laser beam and the second laser beam at the second time interval, the first laser beam and the second laser beam may irradiate the carrier substrate using the scan method along a direction parallel to a long side of the carrier substrate.

In an embodiment, each of the first laser beam and the second laser beam may have a shape of a line beam in a plan view.

In an embodiment, after the first laser beam and the second laser beam are irradiated toward the second side of the carrier substrate, the carrier substrate may be ablated from the flexible substrate.

In an embodiment, the carrier substrate may include glass.

A laser ablation device according to embodiments of the present disclosure includes: a stage on which a carrier substrate, a flexible substrate disposed on a first side of the carrier substrate, and a display element layer disposed on the flexible substrate are disposed; and a light source portion configured to sequentially irradiate a first laser beam and a second laser beam at a first time interval toward a second side of the carrier substrate opposite to the first side in a first area of the carrier substrate overlapping or adjacent to an edge part of the flexible substrate in a plan view and sequentially irradiate the first laser beam and the second laser beam at a second time interval different from the first time interval in a second area of the carrier substrate where the display element layer is disposed.

In an embodiment, the first time interval may be smaller than the second time interval.

In an embodiment, an energy intensity of the first laser beam may be substantially the same as an energy intensity of the second laser beam.

In an embodiment, each of the first laser beam and the second laser beam may be an excimer laser.

In an embodiment, the laser ablation device may further include a transfer portion configured to move the stage together with the carrier substrate, the flexible substrate, and the display element layer in one direction while irradiating the first laser beam and the second laser beam.

In an embodiment, a movement velocity of the stage while the first and second laser beams irradiate the first area may be different from a movement velocity of the stage while the first and second laser beams irradiate the second area.

In an embodiment, the flexible substrate may include a first polyimide layer and a second polyimide layer disposed on the first polyimide layer.

In a method for manufacturing a display device according to an embodiment of the present disclosure, a first laser beam and a second laser beam may be sequentially irradiated at a first time interval toward one side of a carrier substrate in a first area and a third area overlapping or adjacent to an edge part of a flexible substrate in a plan view, and the first laser beam and the second laser beam may be sequentially irradiated at a second time interval different from the first time interval toward one side of the carrier substrate in a second area where a display element layer is formed. The first time interval may be smaller than the second time interval. Accordingly, the carrier substrate may be easily ablated from the flexible substrate. In addition, foreign matter due to an organic insulating layer may not be generated in an area overlapping or adjacent to the edge part of the flexible substrate.

### BRIEF DESCRIPTION OF THE DRAWINGS

Illustrative, non-limiting embodiments will be more clearly understood from the following detailed description in conjunction with the accompanying drawings.

FIGS. 1, 2, 3, and 4 are cross-sectional views for explaining a method for manufacturing a display device according to an embodiment of the present disclosure.

FIG. 5 is an enlarged cross-sectional view of area A of FIG. 3.

FIG. 6 is a cross-sectional view illustrating a laser ablation device according to an embodiment of the present disclosure.

FIG. 7 is a plan view illustrating a method for ablating a carrier substrate from a flexible substrate using first and second laser beams.

FIG. 8 is a graph for explaining a movement velocity of a stage of FIG. 6 over time.

FIG. 9 is a waveform view illustrating oscillation signals of each of the first and second laser beams of FIGS. 6 and 7 over time.

FIG. 10 is a graph illustrating an energy intensity of each of the first and second laser beams of FIG. 9 over time.

### DETAILED DESCRIPTION

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

It will be understood that when an element is referred to as being “on” another element or “connected to” another element, it can be directly on or directly connected to the other element or intervening elements may be present therebetween. In contrast, when an element is referred to as being “directly on” another element, there are no intervening elements present.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially the same” can mean within one or more standard deviations such as 10%, 5% or 2% of the stated value.

Hereinafter, a method for manufacturing a display device and a laser ablation device according to embodiments of the present disclosure will be explained in detail with reference to the accompanying drawings. The same reference numerals are used for the same components in the drawings, and redundant descriptions of the same components will be omitted.

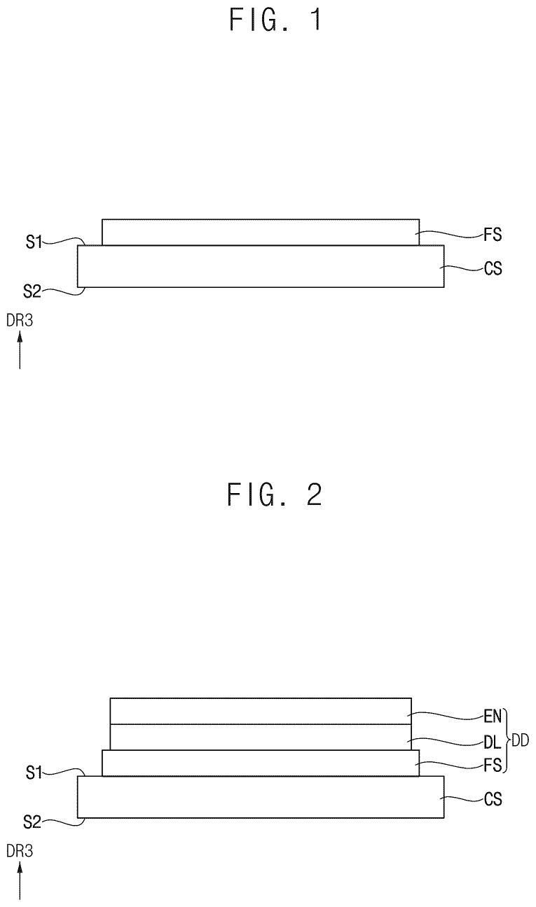

FIGS. 1, 2, 3, and 4 are cross-sectional views for explaining a method for manufacturing a display device according to an embodiment of the present disclosure.

Referring to FIG. 1, a carrier substrate CS may be provided. The carrier substrate CS may include a rigid material to serve as a support during the manufacturing process of a display device DD. In addition, the carrier substrate CS may include a transparent material because it is desirable for light be able to transmit during the detachment process of the carrier substrate CS.

In an embodiment, the carrier substrate CS may include glass. Specifically, the carrier substrate CS may include glass including silicon dioxide (SiO₂) as a main component. For example, the carrier substrate CS may include borosilicate glass, fused silica glass, quartz glass, and/or the like. These can be used alone or in combination with each other.

A flexible substrate FS may be formed on a first surface S1 of the carrier substrate CS. For example, the flexible substrate FS may be formed by coating a polyimide solution on the carrier substrate CS using a spin coating method and then curing the polyimide solution. Alternatively, the flexible substrate FS may be formed by attaching a film-type polyimide substrate to the carrier substrate CS with an adhesive material or by lamination. However, embodiments of the present disclosure are not necessarily limited thereto.

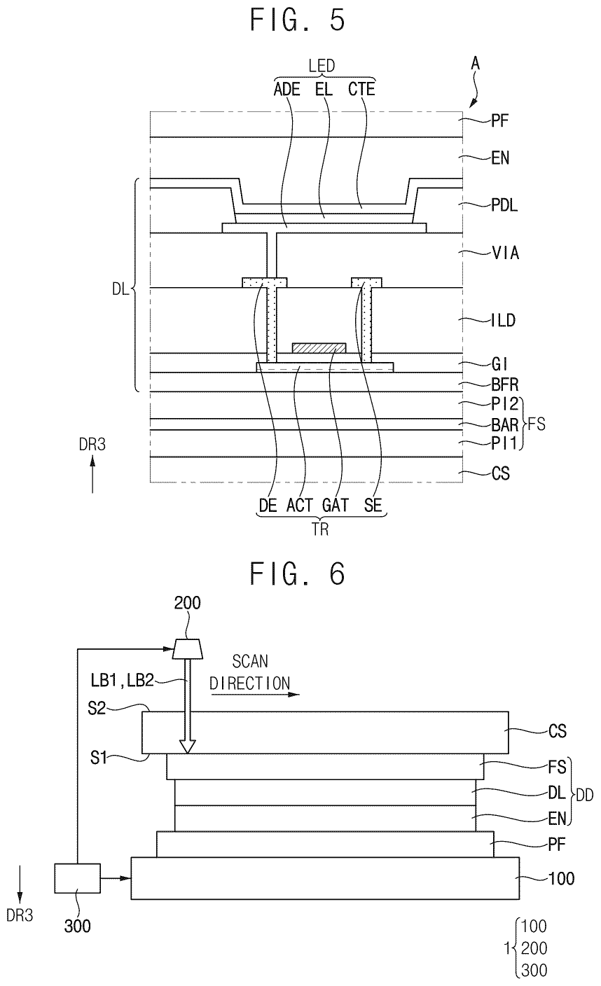

Referring to FIG. 2, a display element layer DL may be formed on the flexible substrate FS. For example, the display element layer DL may include at least one circuit element (e.g., a transistor TR of FIG. 5) and at least one light emitting element (e.g., a light emitting element of FIG. 5) driven by the circuit element.

An encapsulation layer EN may be formed on the display element layer DL. The encapsulation layer EN can prevent impurities, moisture, and/or the like from penetrating into the display element layer DL from the outside. Accordingly, the display device DD including the flexible substrate FS, the display element layer DL, and the encapsulation layer EN may be manufactured.

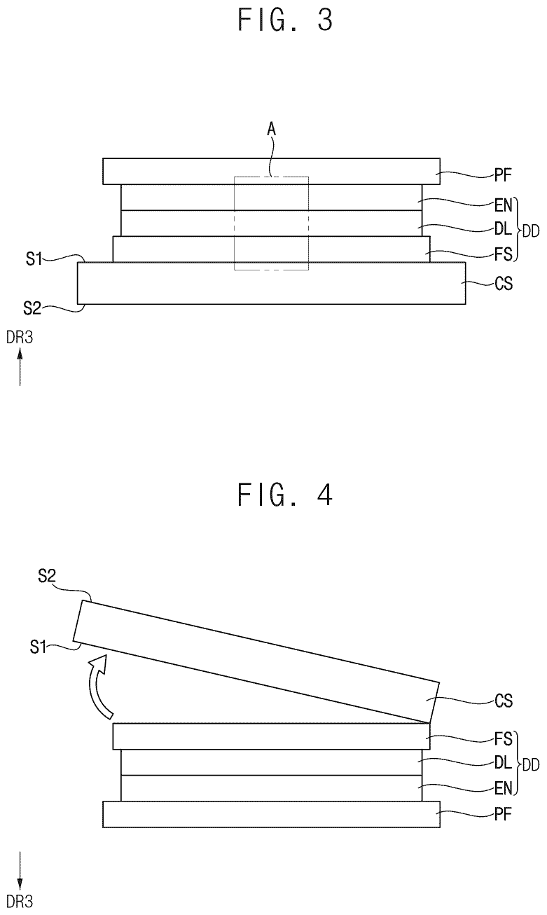

Referring to FIG. 3, a protective film PF may be formed on the encapsulation layer EN. The protective film PF can prevent the encapsulation layer EN from being damaged during the detachment process of the carrier substrate CS. The protective film PF may be removed after detaching the carrier substrate CS.

In an embodiment, in the process that the display device DD is manufactured, the flexible substrate FS, the display device layer DL, and the encapsulation layer EN may be sequentially formed in a thickness direction (i.e., a third direction DR3) on the carrier substrate CS.

After the protective film PF is formed on the encapsulation layer EN, the carrier substrate CS on which the display device DD and the protective film PF is formed may be disposed on a stage (e.g., a stage 100 of FIG. 6).

After the carrier substrate CS is disposed on the stage, the carrier substrate CS may be detached from the display device DD. Detachment process of the carrier substrate CS may be divided into ablating the carrier substrate CS and removing the ablated carrier substrate CS.

In the ablating of the carrier substrate CS, a laser beam having a predetermined energy intensity may be irradiated to an interface between the carrier substrate CS and the flexible substrate FS. In this case, the laser beam having a predetermined energy intensity may be absorbed on one side of the flexible substrate FS facing the first side S1 of the carrier substrate CS. If the absorbed energy exceeds a certain level, the carrier substrate CS may be ablated from the flexible substrate FS. A detailed explanation of this will be provided later.

Referring to FIG. 4, after the carrier substrate CS is ablated from the flexible substrate FS, the carrier substrate CS may be removed.

FIG. 5 is an enlarged cross-sectional view of area A of FIG. 3. For example, FIG. 5 is an enlarged cross-sectional view of a part of the display device DD of FIG. 3. Specifically, FIG. 5 is a cross-sectional view schematically illustrating an area where one pixel of the display device DD of FIG. 3 is disposed.

Referring to FIGS. 3 and 5, the display device DD may include the flexible substrate FS, the display element layer DL, and the encapsulation layer EN. The display element layer DL may include a buffer layer BFR, a transistor TR, a gate insulating layer GI, an interlayer-insulating layer ILD, a via-insulating layer VIA, a pixel defining layer PDL, and a light emitting element LED.

Here, the transistor TR may include an active pattern ACT, a gate electrode GAT, a source electrode SE, and a drain electrode DE, and the light emitting element LED may include an anode electrode ADE, a light emitting layer EL, and a cathode electrode CTE.

The flexible substrate FS may include a transparent material or an opaque material. The flexible substrate FS may be made of a transparent resin substrate. Examples of the transparent resin substrate include a polyimide substrate.

In an embodiment, the flexible substrate FS may include a first polyimide layer PI1, a barrier layer BAR disposed on the first polyimide layer PI1, and a second polyimide layer PI2 disposed on the barrier layer BAR. The barrier layer BAR can prevent penetration of moisture, and/or the like. For example, the barrier layer BAR may include an inorganic material.

For example, each of the first polyimide layer PI1 and the second polyimide layer PI2 may include colored polyimide. Alternatively, each of the first polyimide layer PI1 and the second polyimide layer PI2 may include transparent polyimide.

The buffer layer BFR may be disposed on the flexible substrate FS. The buffer layer BFR can prevent metal atoms or impurities from diffusing from the flexible substrate FS to the transistor TR. In addition, the buffer layer BFR can improve the flatness of the surface of the flexible substrate FS when the surface of the flexible substrate FS is not uniform. For example, the buffer layer BFR may include an inorganic material such as silicon oxide (SiOₓ), silicon nitride (SiNₓ), silicon oxynitride (SiOₓN_{y}), and the like. These can be used alone or in combination with each other.

The active pattern ACT may be disposed on the buffer layer BFR. The active pattern ACT may include a metal oxide semiconductor, an inorganic semiconductor (e.g., amorphous silicon, poly silicon, and the like), or an organic semiconductor. The active pattern ACT may include a source region, a drain region, and a channel region located between the source region and the drain region.

The metal oxide semiconductor may include a binary compound (ABₓ), a ternary compound (ABₓC_{y}), a quaternary compound (ABₓC_{y}D_{z}), and/or the like containing indium (In), zinc (Zn), gallium (Ga), tin (Sn), titanium (Ti), aluminum (Al), hafnium (Hf), zirconium (Zr), magnesium (Mg), and/or the like. For example, the metal oxide semiconductor may include zinc oxide (ZnOₓ), gallium oxide (GaOₓ), tin oxide (SnOx), indium oxide (InOx), indium gallium oxide (“IGO”), indium zinc oxide (“IZO”), indium tin oxide. (“ITO”), indium zinc tin oxide (“IZTO”), indium gallium zinc oxide (“IGZO”), and the like. These can be used alone or in combination with each other.

The gate insulating layer GI may be disposed on the buffer layer BFR. The gate insulating layer GI may sufficiently cover the active pattern ACT and may have a substantially flat upper surface without creating a step around the active pattern ACT. Alternatively, the gate insulating layer GI may cover the active pattern ACT and may be disposed along the profile of the active pattern ACT with a uniform thickness. For example, the gate insulating layer GI may include an inorganic material such as silicon oxide (SiOₓ), silicon nitride (SiNₓ), silicon carbide (SiCₓ), silicon oxynitride (SiOₓN_{y}), silicon oxycarbide (SiOₓC_{y}), and the like. These can be used alone or in combination with each other.

The gate electrode GAT may be disposed on the gate insulating layer GI. The gate electrode GAT may overlap the channel area of the active pattern ACT in a plan view. The gate electrode GAT may include metal, alloy, metal nitride, conductive metal oxide, transparent conductive material, and/or the like. Examples of the metal may include silver (Ag), molybdenum (Mo), aluminum (Al), tungsten (W), copper (Cu), nickel (Ni), chromium (Cr), titanium (Ti), and tantalum (Ta), platinum (Pt), scandium (Sc), and the like. Examples of the conductive metal oxide may include indium tin oxide, indium zinc oxide, and the like. In addition, examples of the metal nitride may include aluminum nitride (AlNₓ), tungsten nitride (WNₓ), chromium nitride (CrNx), and the like. These can be used alone or in combination with each other.

The interlayer-insulating layer ILD may be disposed on the gate insulating layer GI. The interlayer-insulating layer ILD may sufficiently cover the gate electrode GAT and may have a substantially flat upper surface without creating steps around the gate electrode GAT. Alternatively, the interlayer-insulating layer ILD may cover the gate electrode GAT and may be disposed along the profile of the gate electrode GAT with a uniform thickness. For example, the interlayer dielectric layer ILD may include an inorganic material such as silicon oxide, silicon nitride, silicon carbide, silicon oxynitride, silicon oxycarbide, and the like. These can be used alone or in combination with each other.

The source electrode SE and the drain electrode DE may be disposed on the interlayer-insulating layer ILD. The source electrode SE may be connected to the source region of the active pattern ACT through a contact hole penetrating a first part of the gate insulating layer GI and the interlayer-insulating layer ILD, and the drain electrode DE may be connected to the drain region of the active pattern ACT through a contact hole penetrating a second part of the insulating layer GI and the interlayer-insulating layer ILD. For example, each of the source electrode SE and the drain electrode DE may include a metal, alloy, metal nitride, conductive metal oxide, transparent conductive material, and the like. These can be used alone or in combination with each other.

Accordingly, the transistor TR including the active pattern ACT, the gate electrode GAT, the source electrode SE, and the drain electrode DE may be disposed on the flexible substrate F S.

The via-insulating layer VIA may be disposed on the interlayer-insulating layer ILD. The via insulation layer VIA can sufficiently cover the source electrode SE and the drain electrode DE. The via-insulating layer VIA may include an inorganic material or an organic material. In an embodiment, the via-insulating layer VIA may include an organic material. For example, the via-insulating layer VIA may include an organic material such as phenolic resin, polyacrylates resin, polyimides resin, polyamides resin, siloxane resin, epoxy resin, and the like. These can be used alone or in combination with each other.

The anode electrode ADE may be disposed on the via-insulating layer VIA. The anode electrode ADE may be connected to the drain electrode DE (or the source electrode SE) through a contact hole penetrating the via-insulating layer VIA. For example, the anode electrode ADE may include metal, alloy, metal nitride, conductive metal oxide, transparent conductive material, and/or the like. These can be used alone or in combination with each other. In an embodiment, the anode electrode ADE may have a layered structure including ITO/Ag/ITO. However, embodiments of the present disclosure are not necessarily limited thereto.

The pixel defining layer PDL may be disposed on the via-insulating layer VIA. The pixel defining layer PDL may cover the edge of the anode electrode ADE. In addition, an opening exposing at least a part of an upper surface of the anode electrode ADE may be defined in the pixel defining layer PDL. For example, the pixel defining layer PDL may include an inorganic material or an organic material. In an embodiment, the pixel defining layer PDL may include an organic material such as epoxy resin, siloxane resin, and the like. These can be used alone or in combination with each other. In another embodiment, the pixel defining layer PDL may include an inorganic material and/or an organic material containing a light blocking material such as black pigment, black dye, and the like.

The light emitting layer EL may be disposed on the anode electrode ADE. Specifically, the light emitting layer EL may be disposed in the opening of the pixel defining layer PDL. The light emitting layer EL may include an organic material that emits light of a predetermined color. For example, the light emitting layer EL may include an organic material that emits red light, green light, or blue light.

The cathode electrode CTE may be disposed on the pixel defining layer PDL and the light emitting layer EL. For example, the cathode electrode CTE may include metal, alloy, metal nitride, conductive metal oxide, transparent conductive material, and the like. These can be used alone or in combination with each other.

Accordingly, the light emitting element LED including the anode electrode ADE, the light emitting layer EL, and the cathode electrode CTE may be disposed on the flexible substrate FS. The light emitting element LED may be electrically connected to the transistor TR.

The encapsulation layer EN may be disposed on the cathode electrode CTE. The encapsulation layer EN may include at least one inorganic layer and at least one organic layer. For example, the inorganic layer may include silicon oxide, silicon nitride, silicon oxynitride, and/or the like. These can be used alone or in combination with each other. The organic layer may include a cured polymer such as polyacrylate and the like.

FIG. 6 is a cross-sectional view illustrating a laser ablation device according to an embodiment of the present disclosure. FIG. 6 is an upside down view compared to FIGS. 3 and 5 such that the second side S2 of the carrier substrate CS faces a light source portion 200.

Referring to FIG. 6, a laser ablation device 1 may include a stage 100, the light source portion 200, and a transfer portion 300. The light source portion 200 may be a laser generating device, and the transfer portion 300 may be a device including a motor and configured to convey the substrate 100 or the light source portion 200.

The carrier substrate CS, the display device DD disposed on the first side S1 of the carrier substrate CS, and the protective film PF disposed on the display device DD may be disposed on the stage 100. The stage 100 may have a substantially flat upper surface. The display device DD to which the carrier substrate CS is attached may be disposed on the upper surface of the stage 100. In this case, the carrier substrate CS may be disposed to face the light source portion 200 and the protective film PF may be disposed to face the stage 100.

The light source portion 200 may irradiate a laser beam to the carrier substrate CS based on an oscillation signal. Specifically, the light source portion 200 may irradiate the laser beam toward a second surface S2 opposite to the first surface S1 of the carrier substrate CS based on the oscillation signal. The laser beam may pass through the carrier substrate CS and be irradiated to the interface between the carrier substrate CS and the flexible substrate FS.

The laser beam may include a first laser beam LB1 and a second laser beam LB2. The light source portion 200 may sequentially irradiate the first laser beam LB1 and the second laser beam LB2 to the interface between the carrier substrate CS and the flexible substrate FS at predetermined time intervals.

In an embodiment, each of the first laser beam LB1 and the second laser beam LB2 may be an excimer laser. For example, the excimer laser may be a xenon-chloride (XeCl) excimer laser that emits ultraviolet light of about 308 nanometers (nm). However, embodiments of the present disclosure are not necessarily limited to thereto, and various types of lasers may be applied to each of the first laser beam LB1 and the second laser beam LB2. The first laser beam LB1 may be referred to as a master laser, and the second laser beam LB2 may be referred to as a slave laser.

The transfer portion 300 may move the stage 100 in one direction. As the stage 100 moves in the one direction, the first laser beam LB1 and the second laser beam LB2 may irradiate the carrier substrate CS in a scan method. That is, while irradiating the first laser beam LB1 and the second laser beam LB2, the stage 100 may be moved in one direction together with the carrier substrate CS, the display device DD, and the protective film PF. Specifically, the first laser beam LB1 and the second laser beam LB2 may pass through the carrier substrate CS and be irradiated in a scan method on an entire interface between the carrier substrate CS and the flexible substrate FS. That is, the one direction may be a scan direction.

Alternatively, the transfer portion 300 may move the light source portion 200, rather than the stage 100, in a direction (e.g., the second direction DR2) opposite to the one direction, or may move both the stage 100 and the light source portion 200.

In summary, after the first laser beam LB1 and the second laser beam LB2 may pass through the carrier substrate CS and are irradiated in a scan method on the entire interface between the carrier substrate CS and the flexible substrate FS, the carrier substrate CS may be ablated from the flexible substrate FS.

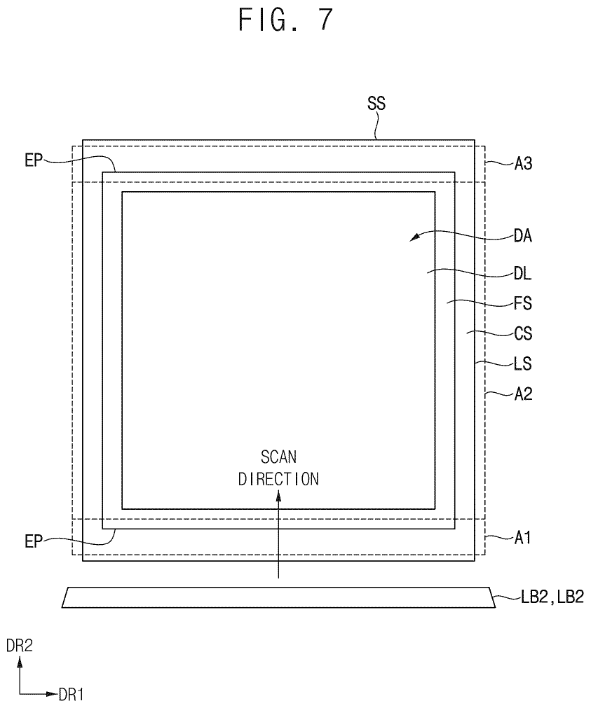

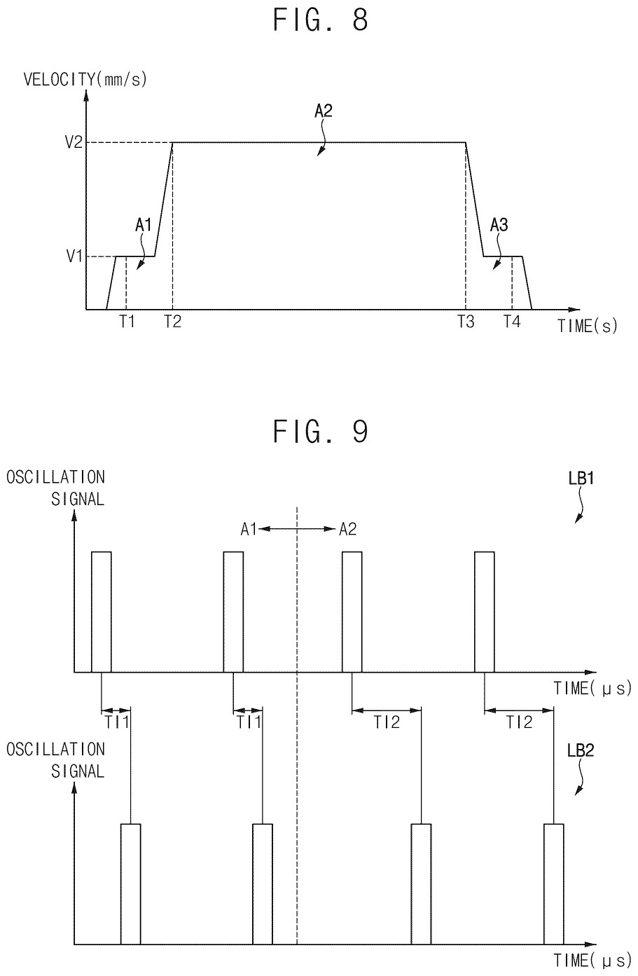

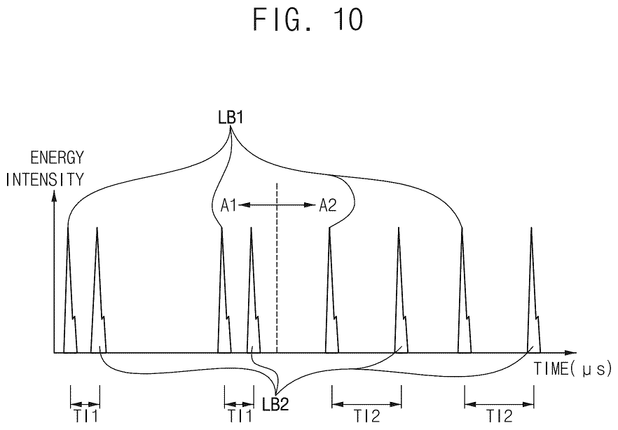

FIG. 7 is a plan view illustrating a method for ablating a carrier substrate from a flexible substrate using first and second laser beams. As used herein, the “plan view” is a view in a thickness direction (i.e., the third direction DR3) of the flexible substrate FS. FIG. 8 is a graph for explaining a movement velocity of a stage of FIG. 6 over time. FIG. 9 is a waveform view illustrating oscillation signals of each of the first and second laser beams of FIGS. 6 and 7 over time. FIG. 10 is a graph illustrating an energy intensity of each of the first and second laser beams of FIG. 9 over time.

Referring to FIGS. 6 and 7, as described above, the first laser beam LB1 and the second laser beam LB2 may pass through the carrier substrate CS and be irradiated in a scan method along the scan direction on the entire interface the carrier substrate CS and the flexible substrate FS. Here, the scan direction may be a second direction DR2.

In an embodiment, the light source portion 200 may irradiate the first laser beam LB1 and the second laser beam LB2 toward the second surface S2 of the carrier substrate CS in a scan method along a direction parallel to a long side LS of the carrier substrate CS. Here, the long side LS of the carrier substrate CS may extend along the second direction DR2, and a short side SS of the carrier substrate CS may extend in a first direction DR1 perpendicular to the second direction DR2. However, embodiments of the present disclosure are not necessarily limited thereto.

In an embodiment, each of the first laser beam LB1 and the second laser beam LB2 may have the shape of a line beam in a plan view. For example, each of the first laser beam LB1 and the second laser beam LB2 may have the shape of a line beam extending in the first direction DR1 perpendicular to the second direction DR2. However, embodiments of the present disclosure are not necessarily limited thereto.

While the flexible substrate FS is disposed on the carrier substrate CS, the carrier substrate CS may be divided into a first area A1, a second area A2, and a third area A3.

The first area A1 may be defined as an area overlapping or adjacent to an edge part EP of the flexible substrate FS in a plan view. The edge part EP of the flexible substrate FS may be a part extending in the first direction DR1 as shown in FIG. 7. The first area A1 may include an edge area of the carrier substrate CS adjacent to the edge part EP and not include an area where the display element layer DL is disposed (i.e., a display area DA) in a plan view.

The third area A3, like the first area A1, may be defined as an area overlapping or adjacent to another edge part EP of the flexible substrate FS opposite to the edge part EP overlapping the first area A1 in a plan view. The third area A3 may be an area facing the first area A1 with the second area A2 in between. Like the first area A1, the third area A3 may include another edge area of the carrier substrate CS adjacent to the another edge part EP and not include the area where the display element layer DL is disposed (i.e., the display area DA).

The second area A2 may be an area located between the first area A1 and the third area A3. Specifically, the second area A2 may be an area including the display area DA where the display element layer DL is disposed.

That is, the light source portion 200 may irradiate the first laser beam LB1 and the second laser beam LB2 in a scan method along the scan direction in an order of the first area A1, the second area A2, and the third area A3 to the entire interface the carrier substrate CS and the flexible substrate FS.

As described above, the stage 100 may be moved in the one direction (e.g., a direction opposite to the second direction DR2) by the transfer portion 300.

Referring further to FIG. 8, the stage 100 may have different moving velocities depending on the area irradiated by the first laser beam LB1 and the second laser beam LB2. For example, a movement velocity (i.e., a movement velocity ranged between V1 and V2) of the stage 100 while the first and second laser beams LB1 and LB2 irradiate the first area A1 and the third area A3 may be different from a movement velocity of the stage 100 while the first and second laser beams LB1 and LB2 irradiate the second area A2 (i.e., a movement velocity V2). In an embodiment, the movement velocity (i.e., a movement velocity ranged between V1 and V2) of the stage 100 while the first and second laser beams LB1 and LB2 irradiate the first area A1 and the third area A3 may be smaller than the movement velocity of the stage 100 while the first and second laser beams LB1 and LB2 irradiate the second area A2.

For example, when a movement time of the stage 100 is between a first time T1 and a second time T2, the first laser beam LB1 and the second laser beam LB2 may irradiate the first area A1 and the stage 100 may have a first movement velocity V1. Specifically, while the first laser beam LB1 and the second laser beam LB2 irradiate the first area A1, the movement velocity of the stage 100 at a specific point may be increase from the first movement velocity V1 to a second movement velocity V2.

For example, when the movement time of the stage 100 is between the second time T2 and a third time T3, the first laser beam LB1 and the second laser beam LB2 may irradiate the second area A2 and the stage 100 may have the second movement velocity V2.

For example, when the movement time of the stage 100 is between the third time T3 and a fourth time T4, the first laser beam LB1 and the second laser beam LB2 may irradiate the third area A3 and the stage 100 may have the first movement velocity V1. Specifically, while the first laser beam LB1 and the second laser beam LB2 irradiate the first area A1, the moving velocity of the stage 100 at a specific point may decrease from the second moving velocity V2 to the first moving velocity V1.

However, embodiments of the present invention are not necessarily limited to thereto, and the stage 100 may have the same moving velocity while the first laser beam LB1 and the second laser beam LB2 are irradiated.

When the moving velocity of the stage 100 is relatively low, the number of overlaps between the first laser beam LB1 and the second laser beam LB2 may be high. On the other hand, when the moving velocity of the stage 100 is relatively high, the number of overlaps between the first laser beam LB1 and the second laser beam LB2 may be small. Here, the number of overlaps of the first laser beam LB1 and the second laser beam LB2 may refer to the number of times the first laser beam LB1 and the second laser beam LB2 overlap each other in a plan view as the first laser beam LB1 and the second laser beam LB2 are irradiated in a scan method in a specific area for a specific time in a scan direction.

Referring further to FIG. 9, the first laser beam LB1 may be irradiated based on a first oscillation signal, and the second laser beam LB2 may be irradiated based on a second oscillation signal. That is, the time at which the first oscillation signal is received may be substantially the same as the time at which the first laser beam LB1 is irradiated, and the time at which the second oscillation signal is received may be substantially the same as the time at which the second laser beam LB2 is irradiated.

In the first area A1, the light source portion 200 may sequentially irradiate the first laser beam LB1 and the second laser beam LB2 at a first time interval TI1 toward the second surface S2 of the carrier substrate CS. That is, in the first area A1, the first laser beam LB1 and the second laser beam LB2 may be sequentially irradiated toward the second surface S2 of the carrier substrate CS in a scan method with a time delay of the second laser beam LB2 corresponding to the first time interval TI1 with respect to the first laser beam LB1.

After the first laser beam LB1 and the second laser beam LB2 are irradiated in the first area A1, the light source portion 200 may sequentially irradiate the first laser beam LB1 and the second laser beam LB2 at a second time interval TI2 different from the first time interval TI1 toward the second surface S2 of the carrier substrate CS in the second area A2. That is, in the second area A2, the first laser beam LB1 and the second laser beam LB2 may be sequentially irradiated toward the second surface S2 of the carrier substrate CS in a scan method with a time delay of the second laser beam LB2 corresponding to the second time interval TI2 with respect to the first laser beam LB1.

After the first laser beam LB1 and the second laser beam LB2 are irradiated in the second area A2, the light source portion 200 may sequentially irradiate the first laser beam LB1 and the second laser beam LB2 at the first time interval TI1 toward the second surface S2 of the carrier substrate CS in the third area A3. That is, in the third area A3, the first laser beam LB1 and the second laser beam LB2 may be sequentially irradiated toward the second surface S2 of the carrier substrate CS in a scan method.

In an embodiment, the first time interval TI1 may be smaller than the second time interval TI2. For example, the first time interval TI1 may be about 0.3 microseconds (μs), and the second time interval TI2 may be about 1666.7 microseconds (μs). However, embodiments of the present disclosure are not necessarily limited thereto.

Referring further to FIG. 10, in an embodiment, the energy intensity of the first laser beam LB1 may be substantially the same as the energy intensity of the second laser beam LB2. That is, the maximum energy intensity of the first laser beam LB1 and the maximum energy intensity of the second laser beam LB2 may be substantially the same.

For example, the energy intensity of the first laser beam LB1 in the first and third areas A1 and A3 and the energy intensity of the first laser beam LB1 in the second area A2 may be substantially the same. The energy intensity of the second laser beam LB2 in the first and third areas A1 and A3 and the energy intensity of the second laser beam LB2 in the second area A2 may be substantially the same. However, embodiments of the present disclosure are not necessarily limited thereto.

Referring again to FIGS. 1, 2, 3, 4, 5, 6, 7, 8, 9, and 10, in embodiments of the present disclosure, the first laser beam LB1 and the second laser beam LB2 may be sequentially irradiated at the first time interval TI1 toward the second side S2 of the carrier substrate CS in the first area A1 and the third area A3 overlapping or adjacent to the edge part EP of the flexible substrate FS in a plan view, and the first laser beam LB1 and the second laser beam LB2 may be sequentially irradiated at the second time interval TI2 different from the first time interval TI1 toward the second area A2 of the carrier substrate CS in the second area A2 where the display element layer DL is formed. The first time interval TI1 may be smaller than the second time interval TI2. Accordingly, the carrier substrate CS may be easily ablated from the flexible substrate FS. In addition, foreign matter due to an organic insulating layer may not be generated in an area overlapping or adjacent to the edge part EP of the flexible substrate FS in a plan view.

Hereinafter, the effects of the present disclosure according to Comparative embodiment and Embodiments will be described.

Referring to Table 1 below, in the Comparative embodiment, a first laser beam and a second laser beam were sequentially irradiated to the interface between the carrier substrate CS and the flexible substrate FS in the first area A1 and the third area A3 at a first time interval of about 1666.7 μs, and were sequentially irradiated to the interface between the carrier substrate CS and the flexible substrate FS in the second area A2 at a second time interval of about 1666.7 μs. The flexible substrate FS was formed using polyimide, and the carrier substrate CS was formed using glass. Each of the first laser beam and the second laser beam is a XeCl excimer laser that emits ultraviolet light of about 308 nm.

In Embodiment 1, the first laser beam LB1 and the second laser beam LB2 were sequentially irradiated to the interface between the carrier substrate CS and the flexible substrate FS in the first area A1 and the third area A3 at the first time interval TI1 of about 0.3 μs, and were sequentially irradiated to the interface between the carrier substrate CS and the flexible substrate FS in the second area A2 at the second time interval TI2 of about 1666.7 μs. The flexible substrate FS was formed using polyimide, and the carrier substrate CS was formed using glass.

In Embodiment 2, the first laser beam LB1 and the second laser beam LB2 were sequentially irradiated to the interface between the carrier substrate CS and the flexible substrate FS in the first area A1 and the third area A3 at the first time interval TI1 of about 0.5 μs, and were sequentially irradiated to the interface between the carrier substrate CS and the flexible substrate FS in the second area A2 at the second time interval TI2 of about 1666.7 μs. The flexible substrate FS was formed using polyimide, and the carrier substrate CS was formed using glass.

In Embodiment 3, the first laser beam LB1 and the second laser beam L2 were sequentially irradiated to the interface between the carrier substrate CS and the flexible substrate FS in the first area A1 and the third area A3 at the first time interval TI1 of about 0.7 μs, and were sequentially irradiated to the interface between the carrier substrate CS and the flexible substrate FS in the second area A2 at the second time interval TI2 of about 1666.7 μs. The flexible substrate FS was formed using polyimide, and the carrier substrate CS was formed using glass.

In Embodiments 1, 2, and 3, each of the first laser beam LB1 and the second laser beam LB32 is a XeCl excimer laser that emits ultraviolet light of about 308 nm.

TABLE 1

| | | | | Transmittance | Whether |
|---|---|---|---|---|---|
| | First time | Second time | Instantaneous | of carrier | foreign |
| | interval | interval | repetition rate | substrate | matter occurs |
| Comparative | 1666.7 μs | 1666.7 μs | 600 Hz | 83.2% | Occurrence |
| embodiment | | | | | |
| Embodiment | 0.3 μs | 1666.7 μs | 3.33 × 10⁶ Hz | 73.2% | Not occurred |
| 1 | | | | | |
| Embodiment | 0.5 μs | 1666.7 μs | 2 × 10⁶ Hz | 78.3% | Not occurred |
| 2 | | | | | |
| Embodiment | 0.7 μs | 1666.7 μs | 1.43 × 10⁶ Hz | 80.7% | Not occurred |
| 3 | | | | | |

As a result, referring to Table 1, it can be conformed that the instantaneous repetition rates of the first laser beam LB1 and the second laser beam LB2 in the first and third areas A1 and A3 according to Embodiments 1, 2, and 3 is relatively greater than the instantaneous repetition rates of the first laser beam LB1 and the second laser beam LB2 in the first and third areas A1 and A3 according to Comparative embodiment. Here, the instantaneous repetition rate refer to a repetition rate that changes instantaneously as the interval between the time when the first laser beam LB1 is irradiated and the time when the second laser beam LB2 is irradiated is adjusted.

When the repetition rate of the laser beam is large, the desorption threshold energy of the laser beam decreases, and when the repetition rate of the laser beam is small, the desorption threshold energy of the laser beam increases. When the desorption threshold energy of the laser beam is low, ablating the carrier substrate may be easy. On the other hand, when the desorption threshold energy of the laser beam is high, ablating the carrier substrate may not be easy.

In addition, according to Embodiments 1, 2, and 3, it can be confirmed that after irradiating the first laser beam LB1 and the second laser beam LB2 to the interface between the carrier substrate CS and the flexible substrate FS, no foreign matter is occurred due to an organic insulating layer in the area overlapping or adjacent to the edge of the flexible substrate FS in a plan view. On the other hand, according to Comparative embodiment, it can be confirmed that after irradiating the first laser beam and the second laser beam to the interface between the carrier substrate CS and the flexible substrate FS, the foreign matter is occurred due to the organic insulating layer in the area overlapping or adjacent to the edge of the flexible substrate FS in a plan view.

When the via-insulating layer VIA of FIG. 5 includes first and second organic insulating layers arranged sequentially, the organic insulating layer may include the same material as the second organic insulating layer and may be formed through the same process as the second organic insulating layer.

In addition, according to Embodiments 1, 2, and 3, it can be confirmed that when the first laser beam LB1 and the second laser beam LB2 are irradiated to the interface between the carrier substrate CS and the flexible substrate FS, the transmittance of the carrier substrate CS satisfies Table 1 above, and the carrier substrate CS is easily ablated from the flexible substrate FS. On the other hand, according to Comparative embodiment, it can be confirmed that when the first laser beam and the second laser beam are irradiated to the interface between the carrier substrate CS and the flexible substrate FS, the transmittance of the carrier substrate CS satisfies Table 1 above, and unnatural ablation of the carrier substrate CS occurs in some areas.

The present disclosure can be applied to a process for manufacturing various display devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present invention. Accordingly, all such modifications are intended to be included within the scope of the present invention as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A method for manufacturing a display device, the method comprising:
forming a flexible substrate on a first side of a carrier substrate;
forming a display element layer on the flexible substrate;
sequentially irradiating a first laser beam and a second laser beam at a first time interval toward a second side of the carrier substrate opposite to the first side in a first area of the carrier substrate overlapping or adjacent to an edge part of the flexible substrate in a plan view; and
sequentially irradiating the first laser beam and the second laser beam at a second time interval different from the first time interval in a second area of the carrier substrate where the display element layer is formed.

2. The method of claim 1, wherein the first time interval is smaller than the second time interval.

3. The method of claim 1, wherein an energy intensity of the first laser beam is substantially the same as an energy intensity of the second laser beam.

4. The method of claim 1, wherein each of the first laser beam and the second laser beam is an excimer laser.

5. The method of claim 1, further comprising:
disposing the flexible substrate on which the display element layer is formed and the carrier substrate on a stage after the forming the display element layer,
wherein the stage is moveable in one direction together with the carrier substrate, the flexible substrate, and the display element layer while irradiating the first laser beam and the second laser beam.

6. The method of claim 5, wherein a movement velocity of the stage while the first and second laser beams irradiate the first area is different from a movement velocity of the stage while the first and second laser beams irradiate the second area.

7. The method of claim 5, wherein a movement velocity of the stage while the first and second laser beams irradiate the first area is smaller than a movement velocity of the stage while the first and second laser beams irradiate the second area.

8. The method of claim 1, wherein the flexible substrate includes a first polyimide layer and a second polyimide layer formed on the first polyimide layer.

9. The method of claim 1, wherein in sequentially irradiating the first laser beam and the second laser beam at the first time interval and sequentially irradiating the first laser beam and the second laser beam at the second time interval,
the first laser beam and the second laser beam irradiate the carrier substrate using a scan method.

10. The method of claim 9, wherein in sequentially irradiating the first laser beam and the second laser beam at the first time interval and sequentially irradiating the first laser beam and the second laser beam at the second time interval,
the first laser beam and the second laser beam irradiate the carrier substrate using the scan method along a direction parallel to a long side of the carrier substrate.

11. The method of claim 1, wherein each of the first laser beam and the second laser beam has a shape of a line beam in a plan view.

12. The method of claim 1, wherein after the first laser beam and the second laser beam are irradiated toward the second side of the carrier substrate, the carrier substrate is ablated from the flexible substrate.

13. The method of claim 1, wherein the carrier substrate includes glass.

14. A laser ablation device comprising:
a stage on which a carrier substrate, a flexible substrate disposed on a first side of the carrier substrate, and a display element layer disposed on the flexible substrate are disposed; and
a light source portion configured to sequentially irradiate a first laser beam and a second laser beam at a first time interval toward a second side of the carrier substrate opposite to the first side in a first area of the carrier substrate overlapping or adjacent to an edge part of the flexible substrate in a plan view and sequentially irradiate the first laser beam and the second laser beam at a second time interval different from the first time interval in a second area of the carrier substrate where the display element layer is disposed.

15. The laser ablation device of claim 14, wherein the first time interval is smaller than the second time interval.

16. The laser ablation device of claim 14, wherein an energy intensity of the first laser beam is substantially the same as an energy intensity of the second laser beam.

17. The laser ablation device of claim 14, wherein each of the first laser beam and the second laser beam is an excimer laser.

18. The laser ablation device of claim 14, further comprising:
a transfer portion configured to move the stage together with the carrier substrate, the flexible substrate, and the display element layer in one direction while irradiating the first laser beam and the second laser beam.

19. The laser ablation device of claim 18, wherein a movement velocity of the stage while the first and second laser beams irradiate the first area is different from a movement velocity of the stage while the first and second laser beams irradiate the second area.

20. The laser ablation device of claim 14, wherein the flexible substrate includes a first polyimide layer and a second polyimide layer disposed on the first polyimide layer.
